(19) United States
(12) Patent Application Publication
(10) Pub. No.: US 2004/0233641 A1
(43) Pub. Date: Nov. 25, 2004

(54) Processor/memory module with foldable substrate

(76) Inventor: Mark Moshayedi, Newport Coast, CA (US)

Correspondence Address: SimpleTech, Inc., c/o Legal Department or Seyed Jalal Sadr, Esq., 3001 Daimler Street, Santa Ana, CA, 92705-5812, US

(21) Appl. No.: 10/845,373

(22) Filed: May 13, 2004

Related U.S. Application Data
(60) Provisional application No. 60/471,544, filed on May 19, 2003.

(51) Int. Cl. H05K 7/20

(52) U.S. Cl. 361/716

(57) ABSTRACT

A packaging approach reduces the overall footprint for interconnecting multiple semiconductor devices. In an embodiment, a processor mounts onto the center of a substrate with flexible appendages and memory components mount to the flexible appendages. The appendages fold over the processor to produce a processor/memory module. The processor/memory module occupies less area on the main printed circuit board than the laterally interconnected processor and memory devices would occupy.

### RELATED APPLICATIONS

The present application claims priority benefits under 35 USC § 119(e) from U.S. Provisional Application No. 60/471,544, filed May 19, 2003, entitled “PROCESSOR/MEMORY MODULE WITH FOLDABLE SUBSTRATE”, the entirety of which is hereby incorporated herein by reference.

### BACKGROUND OF THE INVENTION

1. Field of the Invention

The invention relates to increasing the density of integrated circuits on a printed circuit board, and more particularly, to increasing the density of memory associated with a processor on a printed circuit board.

2. Description of the Related Art

Modern electronic devices, such as computers and the like, typically include semiconductor devices, such as integrated circuits. Integrated circuits are microcircuits formed on a semiconductor substrate and packaged in a ceramic, plastic or epoxy package having multiple external terminals. The microcircuits are wire-bonded within the package to the external terminals. Integrated circuits are commonly found in dual-in-line packages (DIPs), for example, in which the integrated circuit is housed in a rectangular casing with two rows of connecting pins on either side.

When the terminals of the packages are connected to a printed circuit board, the integrated circuits are electrically connected to other integrated circuits and electrical components through or by way of traces on the printed circuit board to form system level electronic circuits.

As the size and complexity of semiconductors increases, packaging schemes have become bulky in providing routing channels for the high number of signals that are routed from the integrated circuit to the package pins. Semiconductor manufacturers have developed several packaging schemes that achieve a smaller package footprint as compared to conventional dual-in-line packages. One such example is a single-in-line package (SIP). In the single-in-line package, the connecting pins protrude from one side of the housing, allowing denser packaging of the semiconductor devices on the printed circuit board.

Additionally, as modern electronic devices are driven to ever increasing functionality and decreasing size, the printed circuit boards within the electronic devices are driven to increased integrated circuit densities. The desire to provide the capability of integrated circuits to be used in relatively small devices limits the extent to which multiple integrated circuits can be laterally interconnected while still fitting within the device.

Lateral extension and interconnection of semiconductor devices tends to lead to relatively long interconnects or traces between devices which increases the signal propagation delay, and thus, decreases the circuit operating speed. Further, lengthy traces increase both the radio-frequency interference (RFI) and electromagnetic interference (EMI) emitted from the printed circuit board.

To avoid the limitations of laterally interconnecting integrated circuits, some manufacturers mount the integrated circuits on a substrate, which is folded onto itself and secured to form a subassembly. The subassembly is then mounted on the main printed circuit board, where the subassembly increases the integrated circuit density of the main printed circuit board by occupying a smaller area than the laterally interconnected semiconductors would occupy.

However, the semiconductors forming the subassembly generate heat, which is often difficult to remove from the densely populated and compact subassembly. If the excess heat is not removed from the subassembly, the semiconductors may not function properly and may ultimately fail.

Further, it is often difficult to test some pins or interconnect nodes on the densely populated subassembly because the pins or interconnect nodes are buried in the folded subassembly. It may also not be possible to access the pins with test equipment. Even if the nodes are not buried, the probes on the test equipment may be too large or bulky to adequately reach areas on the subassembly.

### SUMMARY OF THE INVENTION

The invention relates to packaging a processor and its associated memory onto a subassembly, which mounts onto a main printed circuit board. The subassembly saves space on the main printed circuit board.

In one embodiment, an integrated circuit subassembly that provides for removal of heat from the subassembly increases circuit density on a printed circuit board.

In another embodiment, an integrated circuit subassembly that provides for testing of the subassembly increases circuit density on a printed circuit board.

Another advantage is shorter trace lengths between the processor and the memory input and output signals (I/O's). Thus, increasing the circuit speed, and reducing RFI and EMI emissions.

The subassembly optionally includes a heatsink to remove heat from the processor and memory components.

In an embodiment, the subassembly comprises a printed circuit board comprising a center section, and flexible appendages or wings. A processor mounts in the center section of the printed circuit board along with an optional heat sink. The memory components mount on the flexible appendages of the subassembly. The memory components mount on either the top surface of the appendages or the bottom surface of the appendages. In another embodiment, the memory components mount on both on the top and the bottom surfaces of the appendages.

In an embodiment, the wings fold over the center section such that the first wing folds over the center section, the second wing folds over the first wing, the third wing folds over the second wing, and the fourth wing folds over the third wing. The wings are then secured. In an embodiment, a ball grid array connects the processor/memory assembly to the main board.

In another embodiment, a heatsink mounts onto the top of the processor. The wings fold up to meet the heatsink and are then secured. The heatsink transfers heat away from the processor and the memory components.

In another embodiment, the processor/memory module comprises a printed circuit board comprising a center section, and flexible appendages comprising connectors or sockets. A processor mounts onto the center section of the printed circuit board and a heatsink comprising fins mounts onto the processor. Memory subassemblies, such as, for example, single-in-line memory modules (SIMMs), connect to the connectors, such as, for example, in-line connectors. When the flexible appendages fold upward, the memory subassemblies form a stacked arrangement. The heatsink fins support the stacked arrangement of memory modules and help dissipate at least a portion of the heat generated by the processor and memory components. In an embodiment, the connectors or sockets mount to the top surface or the bottom surface of the flexible appendages. In another embodiment, the connectors or sockets mount to the top and the bottom surfaces of the flexible appendages.

In another embodiment, the processor/memory subassembly comprises a heatsink, and a printed circuit board comprising a center section, and at least one flexible appendage or wing. The heatsink comprises a center and two end sections. A processor mounts onto the center section of the printed circuit board and the center section of the heatsink mounts onto the top of the processor. The flexible wing folds over the processor and the heatsink such that the center section of the heat sink is interposed between the processor and the flexible wing. The wing comprises connectors or sockets positioned on the wing surface. Memory subassemblies, such as, for example, single in-line memory modules (SIMMs), connect to the connectors, such as, for example, in-line connectors, such that the memory subassemblies form a parallel arrangement above the processor. The end sections of the heatsink further comprise fins to transfer at least a portion of the heat generated by the processor and the memory components away from the processor and memory components.

A further embodiment relates to properly terminating the input/output lines between the processor and the memory through impedance matching. Proper termination of the lines, in addition to shorter traces between the processor and the memory, reduces crosstalk between the traces and reduces electromagnetic radiation (EMI) of the traces.

Yet another embodiment of the invention relates to correcting problems on the processor/memory subassembly that are not easily corrected on the main board. For example, the subassembly can be used to correct missing or incorrect traces on the main board.

An additional embodiment of the invention relates to using the processor/memory module to test signals not available on the main board. The flexible wing comprises connectors that connect to test equipment through test cables. The connectors are spaced and dimensioned to facilitate testing. In an embodiment, the processor/memory module permits testing of the memory components. In another embodiment, the module permits the testing of signals and components from the main printed circuit board.

For purposes of summarizing the invention, certain aspects, advantages and novel features of the invention have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

These and other objects and advantages of the present invention will be more apparent from the following description taken in conjunction with the accompanying drawings.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention. Throughout the drawings, reference numbers are re-used to indicate correspondence between referenced elements.

FIG. 1 illustrates an embodiment of a subassembly for packaging a plurality of semiconductor components;

FIG. 2 illustrates of a side view of an embodiment of the subassembly of FIG. 1;

FIG. 3 illustrates a cross-sectional view of a folded embodiment of the module of FIG. 1;

FIG. 4 illustrates an embodiment of a semiconductor module with an optional heatsink;

FIG. 5 illustrates an embodiment of a module with stacked subassemblies;

FIG. 6 illustrates an embodiment of a module with a parallel arrangement of subassemblies; and

FIG. 7 illustrates an embodiment of a module with test capabilities.

### DETAILED DESCRIPTION OF THE PREFERRED EMBODIMENT

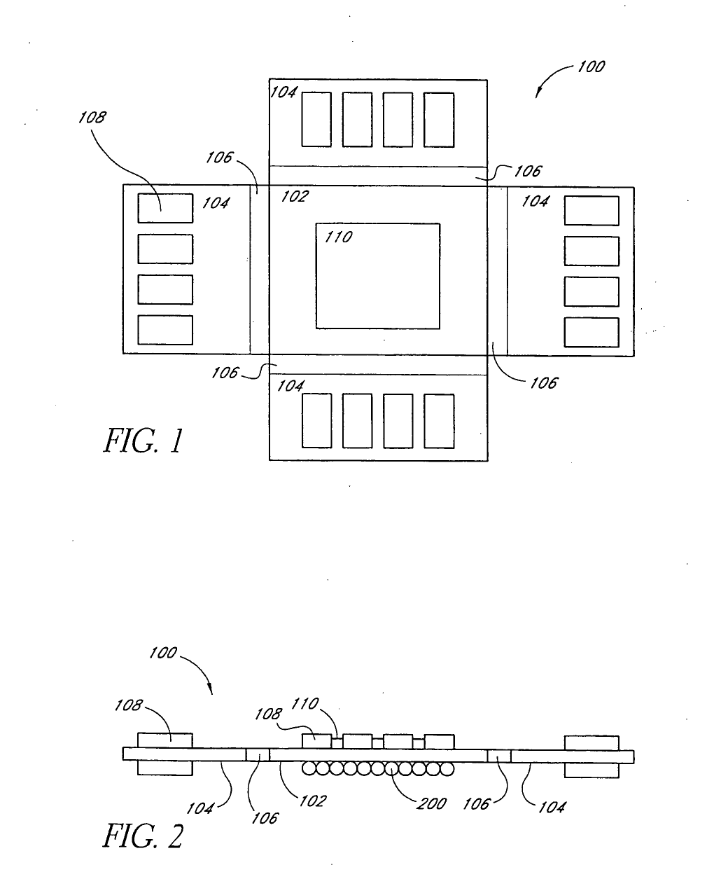

For a more detailed understanding of the invention, reference is first made to FIG. 1. FIG. 1 illustrates an embodiment of a semiconductor subassembly 100 for packaging a plurality of semiconductor components. The subassembly 100 comprises a substrate with a center section 102 and appendages or wings 104. The center section 102 forms the central structure or board for supporting the foldable appendages or wings 104.

In this example, the subassembly 100 has four wings for illustrative purposes only. In other embodiments, the subassembly 100 can have less than four wings 104 or more than four wings 104. It is understood that the number of appendages or wings 104 is not limited to four and the apparatus and methods described below apply to subassemblies 100 with more or less than four appendages 104.

In the illustrated example of FIG. 1, the center section 102 provides a perimeter for attaching the appendages 104. A first appendage 104 has a first end that connects at a first edge of the center section 102 and is attached such that the majority of the appendage 104 extends away from the center section 102. Likewise, any additional appendages 104 are similarly connected at additional perimeter edges of the center section 102.

In an embodiment, the center section 102 comprises a rigid printed wiring board (PWB) made of multiple layers of epoxy glass laminate, as is well know in the art. In another embodiment, the center section 102 comprises, for example, a substrate composed of aluminum oxide, a substrate composed of aluminum nitride, a polyimide flex board, or the like.

Referring in particular to FIG. 1, in one embodiment, the center section 102 has a length of about 4.45 cm (1.75 inches) and a width of about 4.92 cm (1.94 inches). In other embodiments, the center section 102 may be dimensioned and configured in a wide variety of manners, as required or desired.

In an embodiment, the appendages 104 comprise polyimide flex boards, or other flexible circuit boards as are known in the art. The flexible appendage 104 allows the appendage 104 to fold up towards a top surface of the center section 102. In another embodiment, the flexible appendage 104 allows the appendage 104 to fold over the top surface of the center section 102.

Referring in particular to FIG. 1, in one embodiment, the flexible circuit board 104 has a length of about 3.18 cm (1.25 inches) and a width of about 4.92 cm (1.94 inches). In other embodiments, the wings 104 may be dimensioned and configured in a wide variety of manners, as required or desired.

The flexible appendages 104 can connect to the center section 102, for example, through soldering, solder bumps, electrically conductive adhesive dots, pins, and the like.

In another embodiment, the appendages 104 comprise rigid printed wiring boards (PWBs) made of multiple layers of epoxy glass laminate, substrates composed of aluminum oxide, substrates composed of aluminum nitride, or other well known printed wiring board materials. Each rigid appendage 104 further comprises a flexible interconnect 106 between the appendage 104 and the center section 102 such that the connection between the appendage 104 and the center section 102 is foldable. Examples of a flexible interconnect material are polyimide flex board, and the like. It is understood that the invention is not limited to the materials described.

Referring in particular to FIG. 1, in one embodiment, the rigid wing 104 has a length of about 2.54 cm (1.0 inches) and a width of about 4.92 cm (1.94 inches). The flexible interconnect 106 has a length of about 0.64 cm (0.25 inch) and a width of about 4.92 cm (1.94 inches). In other embodiments, the rigid wings 104 and the flexible interconnects 106 may be dimensioned and configured in a wide variety of manners, as required or desired.

In an embodiment, an edge of the flexible interconnect section 106 interposes between layers of the rigid appendage 104, and an opposite edge of the interconnect section 106 interposes between the layers of the rigid center section 102. In other embodiments, the flexible interconnect 106 attaches to the rigid wing 104 and the center section 102 by a wide variety of other methods, such as, for example, soldering, solder bumps, electrically conductive adhesive dots, pins, and the like.

The flexible interconnect section 106 allows the appendage 104 to fold, such as, toward the top surface of the center section 102. In another embodiment, the flexible interconnect 106 permits the appendage 104 to fold over the top surface of the center section 102.

Subassembly 100 further comprises a first semiconductor device 110 mounted onto the top surface of the center section 102. The semiconductor device 110 electrically connects to the center section 102 such that at least one signal from the semiconductor device 110 conducts through traces on the center section 102 to the flexible appendage 104 and/or to the main printed circuit board.

The first semiconductor device 110 comprises an integrated circuit as is well known in the art. In an embodiment, the semiconductor device 110 is a processor. In other embodiments, the processors can comprise controller circuitry, processor circuitry, processors, general purpose single-chip or multi-chip microprocessors, digital signal processors, embedded microprocessors, microcontrollers and the like.

In an embodiment, the semiconductor device 110 is a bare die attached to the center section 102 through solder bumps. A mask applied to the top surface of the center section 102 defines sites for an array of solder bumps in preparation for attaching the semiconductor device 110 to the subassembly 100. The semiconductor device 110 comprises bumps, such as nickel-gold bumps or solder on a surface of the semiconductor die for mating with the array of solder bumps or solderable pads on the center section 102. A reflow process is then used to attach the semiconductor device 110 to the subassembly 100. It is understood that the invention is not limited to the particular solder materials described.

In another embodiment of the invention, the semiconductor device 110 connects to the center section 102 using wire bond edge connections.

In another embodiment, the semiconductor device 110 can be packaged as a dual-in-line package, a single-in-line package, a ball grid array, a pin grid array, a leadless chip, a flip-chip, or any other semiconductor package type as is well know in the art.

Preferably, the semiconductor device 110 connects to the subassembly 100 with high temperature solder.

Subassembly 100 further comprises at least one device 108. In an embodiment, each wing 104 comprises at least one device 108, which mounts onto at least one surface of appendage 104. In another embodiment, at least one device 108 mounts onto at least one surface of at least one appendage 104.

The device 108 electrically connects to the wing 104 such that at least one signal from the device 108 conducts through traces on the wing 104 to the center section 102 and/or the main printed circuit board. The appendages 104 provide electrical interconnects for connecting signals and power supply lines between the semiconductor device 110 and the devices 108.

In an embodiment, the device 108 comprises a connector or a socket, which electrically connects to the appendage 104.

In another embodiment, the device 108 comprises an integrated circuit as is well known in the art. In an embodiment, the device 108 comprises a memory device such as random access memory (RAM), static random access memory (SRAM), non-volatile random access memory (NVRAM), dynamic random access memory (DRAM), multi-bank dynamic random access memory (MDRAM), synchronous dynamic random access memory (SDRAM), magnetoresistive random access memory (MRAM), read only memory (ROM), programmable read only memory (PROM), erasable programmable read only memory (EPROM), electrically erasable programmable read only memory (EEPROM), flash memory, and the like.

In an embodiment, the semiconductor device 108 can be a bare die attached to the appendages 104 using solder applied to sites on the appendages 104. Preferably, a process with pre-bumped semiconductor device 108 uses a solder process while providing either a 95:5 Pb/Sn solder bump or an electroless Ni/Au bump. Other solder bumps, such as a 90:10 Pb/Sn solder bump, and the like can also be used. Preferably, the bump height is approximately 25-50 mm. It is understood that the invention is not limited to the particular solder materials described.

In another embodiment of the invention, the semiconductor devices 108 connect to the wings 104 using wire bond edge connections.

In another embodiment, the semiconductor device 108 can be packaged as a dual-in-line package, a single-in-line package, a ball grid array, a pin grid array, a leadless chip, a flip-chip, or any other semiconductor package type as is well know in the art.

Preferably, the devices 108 connect to subassembly 100 with high temperature solder.

In an embodiment, the semiconductor devices 108 comprise identical integrated circuits. In another embodiment, the semiconductor devices 108 comprise various integrated circuits.

FIG. 2 illustrates a side view of an embodiment of the subassembly 100 of FIG. 1. The wings 104 connect to the center section 102 through the flexible interconnects 106. The semiconductor device 110 mounts onto the top surface of the center section 102 and devices 108 mount onto the wings 104. In the embodiment shown in FIG. 2, the semiconductor devices 108 mount onto the top surfaces, and the bottom surfaces of the appendages 104. In other embodiments, the semiconductor devices 108 mount to appendages 104 on only the top surfaces, or on only the bottom surfaces.

The subassembly 100 further comprises a connecting device 200. The connecting device 200 electrically connects signals and power supply lines of the subassembly 100 with a main printed circuit board. In the embodiment shown in FIG. 2, the connecting device 200 comprises a ball grid array. Other connecting devices 200 can comprise, for example, surface mount pads, surface mount contacts, solder bumps, pins, through-hole pins, and the like. Preferably, subassembly 100 connects to the main printed circuit board with low temperature solder.

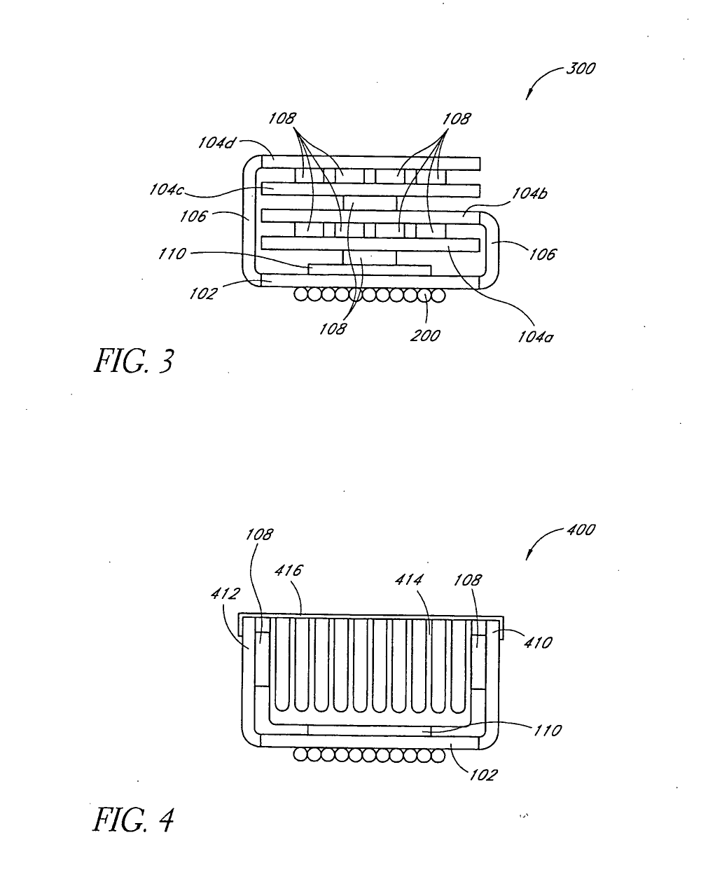

FIG. 3 illustrates a cross-sectional view of an embodiment of a module 300. The appendages 104, comprising devices 108, fold over the center section 102 in the subassembly 100 to form the three-dimensional module 300. A first flexible wing 104a folds over the center section 102 and semiconductor device 110. Thus, the first flexible appendage 104a resides over the semiconductor device 110. A second flexible appendage 104b folds over the first flexible appendage 104a. Likewise, a third flexible appendage 104c folds over the second flexible appendage 104b, and a fourth flexible appendage 104d folds over the third flexible appendage 104c. The connecting device 200 connects the module 300 to the main printed circuit board as described above.

In an embodiment, the module 300 has a footprint approximately the same size as the footprint of the semiconductor device 110. In another embodiment, the module 300 occupies substantially less area than the area occupied by laterally interconnecting the semiconductor device 110 and the devices 108 on the main printed circuit board.

Referring in particular to FIG. 3, in one embodiment, the module 300 has a length of about 5.40 cm (2.125 inches), a width of about 4.93 cm (1.94 inches) and a height of about 3.81 cm (1.50 inches). In other embodiments, the module 300 may be dimensioned and configured in a wide variety of manners, as required or desired.

In an embodiment of the invention, a non-conductive insulating film, such as polyimide film, for example, is applied to the bottom surface of the appendages 104a-d to provide electrical isolation between the folded layers of the module 300. Alternatively, a low flow non-conductive epoxy adhesive could be used to secure the folded appendages 104a-d above the center section 102. For applications requiring enhanced thermal conductivity, an adhesive with improved thermal properties comprising aluminum nitride, boron nitride or the like could be used.

In another embodiment, a thermal cap can reside over the center section 102 and foldable appendages 104a-d provides thermal heat transfer from the devices 110 and 108 to outside the module 300. The thermal cap additionally provides moisture protection for the devices 110 and 108, and electromagnetic interference (EMI) ground shielding.

In a further embodiment of the invention, the subassembly 100 comprises one appendage 104, which is folded over the center section 102 to form the module 300. In another embodiment of the invention, the subassembly 100 comprises less than four or more than four appendages 104, which are folded over to form the module 300.

In an embodiment of the invention, the semiconductor device 110 comprises a processor, the devices 108 comprise memory devices, and the module 300 comprises a processor/memory subassembly.

FIG. 4 illustrates an embodiment of a subassembly or module 400 comprising the center section 102 and two flexible appendages 410, 412 located on opposite sides of the center section 102. The semiconductor device 110 mounts onto the center section 102, as described above. The devices 108 mount onto the appendages 410 and 412 as described above. The connecting device 200 connects the module 400 to the main printed circuit board as described above.

In this example, the subassembly 400 has two wings 410, 412 for illustrative purposes only. In other embodiments, the subassembly 400 can have less than two wings 410, 412 or more than two wings 410, 412. It is understood that the number of appendages or wings 410, 412 is not limited to two and the apparatus and methods described below apply to subassemblies 400 with more or less than two appendages 410, 412.

Referring in particular to FIG. 4, in one embodiment, the center section 102 has a length of about 5.72 cm (2.25 inches), a width of 5.72 cm (2.25 inches). In one embodiment, the wings 410, 412 have a length of about 3.18 cm (1.25 inches) and a width of about 5.72 cm (2.25 inches). In other embodiments, the center section 102 and the wings 410, 412 may be dimensioned and configured in a wide variety of manners, as required or desired.

Module 400 further comprises a heatsink 414. The shape of the heatsink 414 is a rectangular solid. In other embodiments, the heatsink 414 can be, for example, a polyhedron such as a cube, a rectangular prism, a pyramid, or the like. In yet other embodiments, the heatsink 414 can be circular, such as, for example, a sphere, a cylinder, or the like.

Referring in particular to FIG. 4, in one embodiment, the heatsink 414 has a length of about 5.08 cm (2.0 inches), a width of 5.08 cm (2.0 inches), and a height of about 3.18 cm (1.25 inches). In other embodiments, the heatsink 414 may be dimensioned and configured in a wide variety of manners, as required or desired.

Typically, heat sinks comprise a plurality of fins. The fins provide the heatsink with a greater surface area from which heats dissipates. The heatsink 414 comprises a base and a plurality of fins. In an embodiment, the fins form vertical planes placed perpendicular to and spaced longitudinally across the heatsink base.

Referring in particular to FIG. 4, in one embodiment, the heatsink 414 has 11 fins. Each fin has a width of about 0.16 cm (0.0625 inch), a length of about 5.08 cm (2.0 inches), and a height of about 2.38 cm (0.9375 inches). The fins are spaced about 0.656 cm (0.22 inch) apart. In other embodiments, the number of fins of heatsink 414 may be more than 11 or less than 11, as required or desired. The fins of heatsink 414 may be dimensioned and configured in a wide variety of manners, as required or desired.

In another embodiment, for example, the fins can form posts placed perpendicular to and spaced in an array pattern across the length and width of the base. The posts may be square, rectangular, polygonal, circular, or the like in cross section. In other embodiments, the structure of the heatsink 414 may be configured in a wide variety of manners, as required or desired.

In an embodiment, the heatsink 414 is extruded aluminum. Other typical heatsink materials include, for example, copper, copper coil, stainless steel, iron, metal alloys, or any other thermally conductive material. The heatsink 414 can be fabricated by a wide variety of methods, such as, for example, extrusion, stamping folding, drawing, molding, casting, forging, welding, bonding, punching CNC machining, or the like. The finish on the heatsink 414 can be chromated, anodized, powder coated, or the like. It is understood that the heatsink 414 is not limited to the particular materials, fabrication methods, and finishes described.

The heatsink 414 sets on the semiconductor device 110 and the appendages 410, 412 fold upward such that the devices 108 meet the heatsink 414. In an embodiment, the appendages 410, 412 and the center section 102 form approximately a right angle.

Preferably, a non-conductive thermal grease placed between the semiconductor device 110 and the heatsink 414 and/or between the devices 108 and the heatsink 414 provides greater thermal conductivity between the devices 110, 108 and the heatsink 414.

The subassembly 400 further comprises at least one clamp 416, which holds the wings 410 and 412 against the heatsink 414. In an embodiment, the clamp 416 is a metal strap, which clips over the sides of the appendages 410, 412 and rests on the fins of the heatsink 414. In an embodiment, the clamp 416 is fabricated from steel, aluminum, plastic, or the like. It is understood that the clamp 416 is not limited to the particular materials described.

Referring in particular to FIG. 4, in one embodiment, the clamp 416 has a length of about 6.99 cm (2.75 inches), a width of about 0.64 cm (0.25 inch), and a height of about 0.64 cm (0.25 inch). The clamp 416 may be dimensioned and configured in a wide variety of manners, as required or desired.

In another embodiment, the module 400 comprises more than two or less than two foldable appendages which fold upward to meet the heatsink 414.

In an embodiment, the semiconductor device 110 is a processor, the devices 108 are memory components, and the module 400 is a processor/memory subassembly.

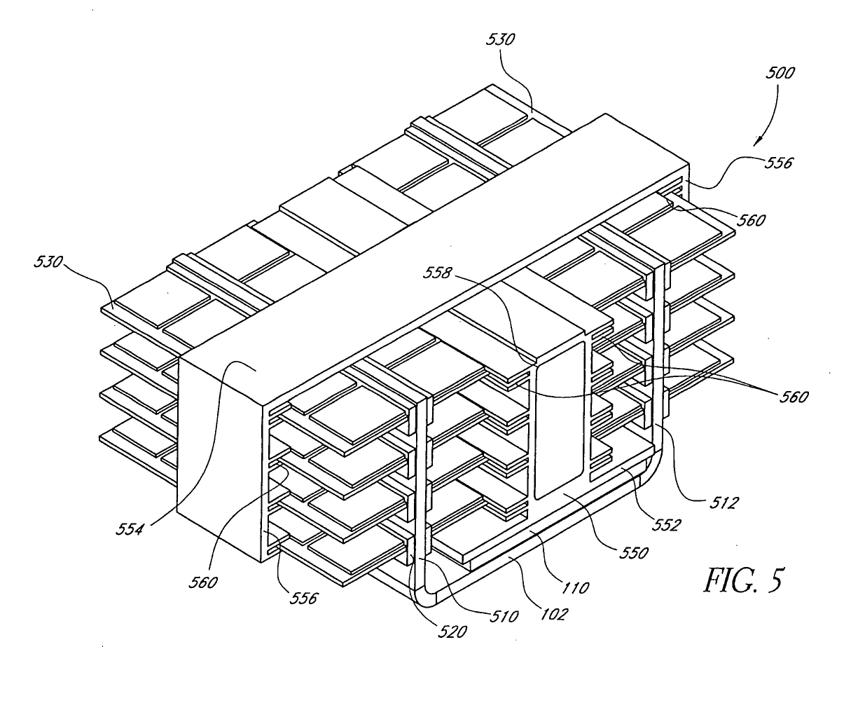

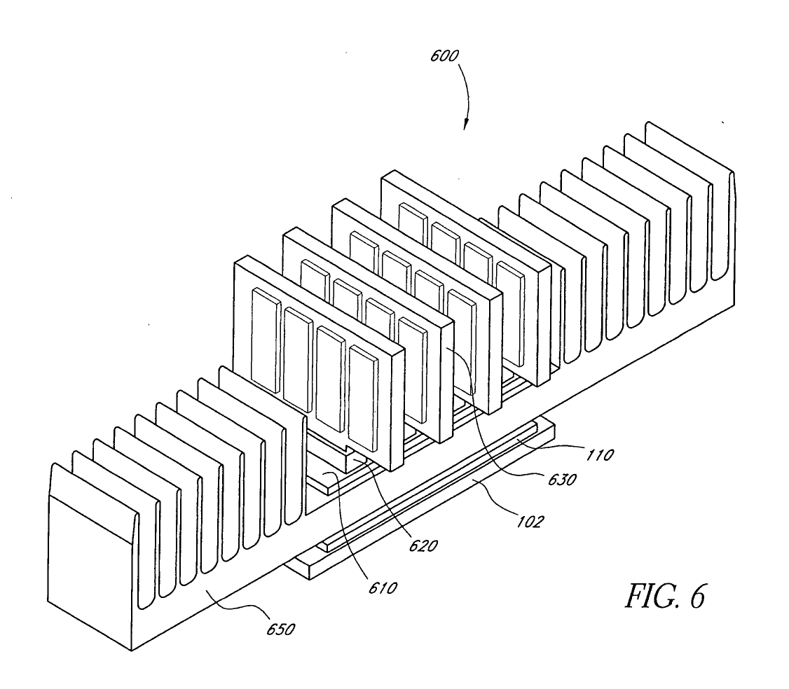

FIG. 5 illustrates an embodiment of a subassembly or module 500. The module 500 comprises a substrate comprising the center section 102 and a plurality of flexible appendages 510, 512. The module 500 further comprises the semiconductor device 110 mounted to the center section 102 as described above.

In this example, the subassembly 500 has two wings 510, 512 for illustrative purposes only. In other embodiments, the subassembly 500 can have less than two wings 510, 512 or more than two wings 510, 512. It is understood that the number of appendages or wings 510, 512 is not limited to two and the apparatus and methods described below apply to subassemblies 500 with more or less than two appendages 510, 512.

Referring in particular to FIG. 5, in one embodiment, the center section 102 has a length of about 7.62 cm (3.0 inches), and a width of about 5.72 cm (2.25 inches). In one embodiment, the wings 510, 512 have a length of about 5.72 cm (2.25 inches) and a width of about 5.72 cm (2.25 inches). In other embodiments, the center section 102 and the wings 510, 512 may be dimensioned and configured in a wide variety of manners, as required or desired.

The flexible appendages 510, 512 further comprise a plurality of connectors or sockets 520 and a plurality of memory subassemblies 530.

The memory subassembly 530 comprises a printed wiring board, at least one memory device, and an edge connector, such as, for example, found in single in-line memory modules (SIMMs) or dual in-line memory modules (DIMMs).

In an embodiment, the memory device of the memory subassembly 530 comprises, for example, random access memory (RAM), static random access memory (SRAM), non-volatile random access memory (NVRAM), dynamic random access memory (DRAM), multi-bank dynamic random access memory (MDRAM), synchronous dynamic random access memory (SDRAM), magnetoresistive random access memory (MRAM), read only memory (ROM), programmable read only memory (PROM), erasable programmable read only memory (EPROM), electrically erasable programmable read only memory (EEPROM), flash memory, and the like.

The edge connectors on the memory subassemblies 530 connect to the connectors or sockets 520. The connectors or sockets 520 mount to the foldable appendages 510, 512 on the top and on the bottom surfaces of the foldable appendages 510, 512. In another embodiment, the connectors or sockets 520 mount to the top surfaces or the bottom surfaces of the foldable wings 510, 512. The connectors 520 electrically connect to the wings 510, 512 such that at least one signal from the memory subassembly 530 conducts through traces on the wings 510, 512 to the center section 102.

Referring in particular to FIG. 5, in one embodiment, the memory subassembly 530 has a length of about 2.54 cm (1.0 inches), and a width of about 5.72 cm (2.25 inches). In other embodiments, the memory subassembly 530 may be dimensioned and configured in a wide variety of manners, as required or desired.

The module 500 further comprises a heatsink 550. The heatsink 550 comprises a base 552, a top section 554, a plurality of sides 556, a hollow rectangular center support 558, and a plurality of fins 560. The center support 558 sets between the base 552 and the top section 554, and includes fins 560. The fins 560 extend horizontally from the center support 558, toward the wings 510, 512, and parallel to the base 552. The sides 556 extend down from opposite edges of the top section 554 and also include fins 560. The fins 560 extend horizontally from the sides 556, toward the center section 558, and parallel to the base 552.

Referring in particular to FIG. 5, in one embodiment, the heatsink 550 has a length of about 16.24 cm (6.0 inches), a width of about 5.72 cm (2.25 inches), and a height of about 3.08 cm (2.0 inches). In other embodiments, the heatsink 550 may be dimensioned and configured in a wide variety of manners, as required or desired.

Again, referring in particular to FIG. 5, in one embodiment, the base 552 has a length of about 5.72 cm (2.25 inches) and a width of about 5.72 cm (2.25 inches) and the top section 554 has a length of about 17.78 cm (7.0 inches) and a width of about 5.72 cm (2.25 inches). The sides 556 have a height of about 4.45 cm (1.75 inches) and a width of about 5.72 cm (2.25 inches). The hollow center support 558 has a length of about 1.91 cm (0.75 inch), a width of about 5.72 cm (2.25 inches) and a height of about 5.08 cm (2.0 inches). The fins 560 have a length of about 0.95 cm (0.375 inch) and a width of about 5.72 cm (2.25 inch). In other embodiments, the base 552, the top section 554, the sides 556, the hollow center support 558, and the fins 560 may be dimensioned and configured in a wide variety of manners, as required or desired.

Preferably, the heatsink 550 is extruded aluminum. Other typical heatsink materials include, for example, copper, copper coil, stainless steel, iron, metal alloys, or any other thermally conductive material. The heatsink 550 can be fabricated by a wide variety of methods, such as, for example, extrusion, stamping folding, drawing, molding, casting, forging, welding, bonding, punching CNC machining, or the like. The finish on the heatsink 550 can be chromated, anodized, powder coated, or the like. It is understood that the heatsink 550 is not limited to the particular materials, fabrication methods, and finishes described.

The heatsink 550 mounts onto the semiconductor device 110. Preferably, a non-conductive thermal grease placed between the semiconductor device 110 and the heatsink 550 provides greater thermal conductivity between the semiconductor device 110 and the heatsink 550.

The foldable appendages 510, 512, comprising the memory subassemblies 530 and the connectors or sockets 520, fold upward with respect to the center section 102. The memory subassemblies 530 form a stacked arrangement within the module 500. The fins 560 on the heatsink 550 are placed such that when one edge of the memory subassembly 530 connects to the connector or socket 520, the fin 560 supports the opposite edge of the memory subassembly 530.

Preferably, a non-conductive thermal grease placed between the memory subassemblies 530 and the heatsink 550 provides greater thermal conductivity between the memory subassemblies 530 and the heatsink 550.

Again, referring in particular to FIG. 5, in one embodiment, four connectors 520 mount on the top surfaces of the wings 510, 512 and four connectors mount on the bottom surfaces of the wings 510, 512. Memory subassemblies 530 connect to each of the 16 connectors 520 in the module 500. In other embodiments, the connectors 520 can be spaced and configured in a wide variety of manners, as required or desired.

Again, referring in particular to FIG. 5, in one embodiment, the fins 560 of the heatsink 550 are grouped in four pairs along each side 556 and along each of the sides of the center support 558 and are directed toward the flexible wings 510, 512. The fins 560 are spaced such that a fin pair supports an edge of the memory subassembly 530, and the connector 520 connects to an opposite edge of the memory subassembly 530. In other embodiments, the fins 560 can be spaced and configured in a wide variety of manners, as required or desired.

The heatsink 550 supports the memory subassemblies 530. In addition, the heatsink 550 transfers at least a portion of the heat generated by the semiconductor device 110 and the memory subassemblies 530 away from the semiconductor device 110 and the memory subassemblies 530.

In an embodiment, the semiconductor device 110 comprises a processor and the module 500 comprises a processor/memory subassembly. In an embodiment, the footprint of the processor/memory module 500 is significantly less than the area the laterally connected memory devices on the memory subassemblies 530 and processor 110 would occupy on the main printed circuit board.

FIG. 6 illustrates an embodiment of a subassembly or module 600 comprising a substrate, which comprises the center section 102 and a flexible appendage 610 positioned on an edge of the center section 102. The module 600 further comprises the semiconductor device 110 mounted to the center section 102, as described above.

In this example, the subassembly 600 has one wing 610 for illustrative purposes only. In other embodiments, the subassembly 600 can have more than one wing 610. It is understood that the number of appendages or wings 610 is not limited to one and the apparatus and methods described below apply to subassemblies 600 with more than one wing 610.

Referring in particular to FIG. 6, in one embodiment, the center section 102 has a length of about 7.62 cm (3.0 inches), and a width of about 5.72 cm (2.25 inches). In one embodiment, the wing 610 has a length of about 5.72 cm (2.25 inches) and a width of about 6.35 cm (2.5 inches). In other embodiments, the center section 102 and the wing 610 may be dimensioned and configured in a wide variety of manners, as required or desired.

The flexible appendage 610 further comprises a plurality of connectors or sockets 620 and a plurality of memory subassemblies 630.

The memory subassembly 630 comprises a printed wiring board, a plurality of memory devices and an edge connector, such as, for example, found in single in-line memory modules (SIMMS) or dual in-line memory modules (DIMMs).

In an embodiment, the memory subassembly 630 comprises at least one memory device, such as, for example, random access memory (RAM), static random access memory (SRAM), non-volatile random access memory (NVRAM), dynamic random access memory (DRAM), multi-bank dynamic random access memory (MDRAM), synchronous dynamic random access memory (SDRAM), magnetoresistive random access memory (MRAM), read only memory (ROM), programmable read only memory (PROM), erasable programmable read only memory (EPROM), electrically erasable programmable read only memory (EEPROM), flash memory, and the like.

Referring in particular to FIG. 6, in one embodiment, the memory subassembly 630 has a length of about 2.54 cm (1.0 inches), and a width of about 5.72 cm (2.25 inches). In other embodiments, the memory subassembly 630 may be dimensioned and configured in a wide variety of manners, as required or desired.

The edge connectors on the memory subassemblies 630 connect to the connectors 620. The connectors or sockets 620 mount to the foldable appendage 610 on the bottom surface of the foldable appendage 610. In another embodiment, the connectors or sockets 620 mount to the top surface or both the top and bottom surfaces of the flexible wing 610. The connectors 620 electrically connect to the wing 610 such that at least one signal from the memory subassembly 630 conducts through traces on the wing 610 to the center section 102.

Referring in particular to FIG. 6, in one embodiment, there are four connectors 620 mounted to the flexible wing 610. The connectors 620 are spaced about 1.6 cm (0.625 inch) apart. In other embodiments, the number of connectors 620 on the flexible wing 610 may vary, as required or desired. In other embodiments, the connectors 620 may be spaced and configured in a wide variety of manners, as required or desired.

The module 600 further comprises a heatsink 650. The heatsink 650 comprises a base, and a plurality of fins. In an embodiment, the fins form vertical planes placed perpendicular to and spaced longitudinally across the heatsink base. The fins are located on either side of the heatsink base, leaving a center area of the heatsink 650 available to support the folded wing 610.

Referring in particular to FIG. 6, in one embodiment, the heatsink 650 has a length of about 16.24 cm (6.0 inches), a width of about 5.72 cm (2.25 inches), and a height of about 1.91 cm (0.75 inches). In other embodiments, the heatsink 650 may be dimensioned and configured in a wide variety of manners, as required or desired.

Again, referring in particular to FIG. 6, in one embodiment, the base of the heatsink 650 has a length of about 16.24 cm (6.0 inches), a width of about 5.72 cm (2.25 inches), and a height of about 0.64 cm (0.25 inch). The fins have a thickness of about 0.16 cm (0.0625 inch), a width of about 5.72 cm (2.25 inch), and a height of about 1.27 cm (0.5 inch). In other embodiments, the base and the fins of the heatsink 650 may be dimensioned and configured in a wide variety of manners, as required or desired.

Again referring in particular to FIG. 6, in one embodiment, the heatsink fins are grouped into two sets, and each set of fins is positioned on an end section of the heatsink 650. Each set of fins comprises nine fins and the fins are spaced about 0.64 cm (0.25 inch) apart. In other embodiments, the fins of heatsink 650 may be spaced and configured in a wide variety of manners, as required or desired.

Preferably, the heatsink 650 is extruded aluminum. Other typical heatsink materials include, for example, copper, copper coil, stainless steel, iron, metal alloys, or any other thermally conductive material. The heatsink 650 can be fabricated by a wide variety of methods, such as, for example, extrusion, stamping folding, drawing, molding, casting, forging, welding, bonding, punching CNC machining, or the like. The finish on the heatsink 650 can be chromated, anodized, powder coated, or the like. It is understood that the heatsink 650 is not limited to the particular materials, fabrication methods, and finishes described.

The center section of the heatsink 650 mounts to an upper surface of the semiconductor device 110. The flexible appendage 610, comprising the connectors or sockets 620 and the memory subassemblies 630, folds over the center of the heatsink 650 such that the heatsink 650 interposes between the flexible appendage 610 and the semiconductor device 110.

Preferably, a non-conductive thermal grease placed between the semiconductor device 110 and the heatsink 650 and/or between the flexible wing 610 and the heatsink 650 provides greater thermal conductivity between the devices 110, 620, and the heatsink 650.

Again referring in particular to FIG. 6, in one embodiment, four connectors mount onto the bottom surface of the flexible wing 610. The memory subassemblies 630 connect to the connectors or sockets 620. When the flexible wing 610 folds over the semiconductor device 110 and the heatsink 650, the four connectors 620 set on top of the center portion of the heatsink 650. The memory subassemblies 630 form a parallel arrangement within the module 600.

The heatsink 650 supports the memory subassemblies 630. In addition, the heatsink 650 conducts at least a portion of the heat generated by the semiconductor device 110 and the memory subassemblies 630 away from the semiconductor device 110 and the memory subassemblies 630.

In an embodiment, the semiconductor device 110 comprises a processor and the module 600 comprises a processor/memory subassembly. When the module 600 mounts to the main printed circuit board, the area of the main printed circuit board below the fins of the subassembly 600 is available to receive additional integrated circuits. The area of the main printed circuit board that the subassembly occupies is substantially less than the area the laterally connected processor 110 and the memory devices on the memory subassemblies 630 would occupy.

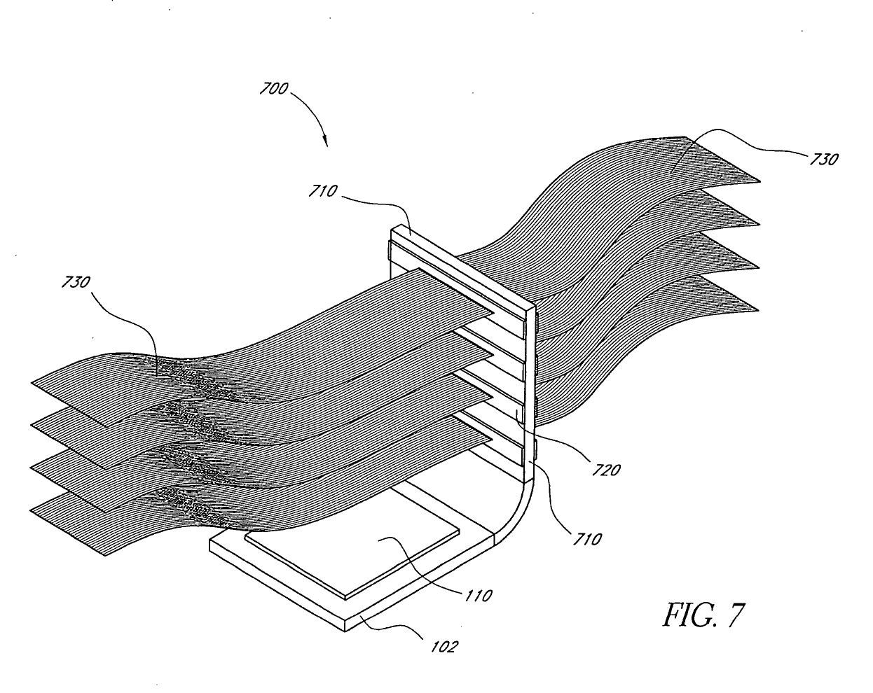

FIG. 7 illustrates an embodiment of a module or subassembly 700 that can be used for testing at least a portion of the module 700 and/or at least a portion of the main circuit board. The module 700 comprises a substrate, which comprises the center section 102 and at least one flexible wing 710.

In this example, the subassembly 700 has one wing 710 for illustrative purposes only. In other embodiments, the subassembly 700 can have more than one wing 710. It is understood that the number of appendages or wings 710 is not limited to one and the apparatus and methods described below apply to subassemblies 700 with more than one appendage 710.

Referring in particular to FIG. 7, in one embodiment, the center section 102 has a length of about 7.62 cm (3.0 inches), and a width of about 5.72 cm (2.25 inches). In one embodiment, the wing 710 has a length of about 5.72 cm (2.25 inches) and a width of about 5.72 cm (2.25 inches). In other embodiments, the center section 102 and the wing 710 may be dimensioned and configured in a wide variety of manners, as required or desired.

The flexible appendage 710 further comprises at least one connector 720, which can connect to test equipment through test equipment cables 730. The center section 102 may optionally comprise semiconductor devices 108, 110, which mount to the center section as described above.

Again, referring in particular to FIG. 7, in one embodiment, four connectors 720 mount to a top surface of flexible wing 720 and four connectors mount to a bottom surface of flexible wing 720. The connectors 720 are spaced about 1.27 cm (0.5 inch) apart. In other embodiments, the number of connectors may vary, as required or desired. In other embodiments, the connectors 720 may be spaced and configured in a wide variety of manners, as required or desired.

In a further embodiment of the invention, connectors 720 can mount to a top surface, a bottom surface or both the top and bottom surfaces of the at least one flexible appendage 710. The connectors 720 electrically connect to the wing 710 such that al least one signal from the wing 710, the center section 102, and/or the main printed circuit board is available at the connector 720.

The test cables 730 connect to the connectors 720. The test cables 730 can connect to a variety of test equipment. Examples of test equipment are logic analyzers, harmonic analyzers, oscilloscopes, function generators, multimeters, and the like.

Timing, signal levels, impedance, and the like, of the semiconductor devices on the subassembly 700 and on the main printed circuit board may be monitored or tested through the module 700. Further, the module 700 may allow access to signals not available for testing on the main printed circuit board.

FIG. 7 shows the module 700 unfolded into a test ready position, with the test cables 730 connected to the connectors 720.

The test subassembly 700 can be folded and secured as illustrated in FIG. 3 when not being used for testing.

The folded subassembly packaging approach described herein reduces the overall area for interconnecting multiple semiconductor devices on the main printed circuit board. In an embodiment of the invention, the footprint of the modules 300, 400, 500, 600, 700 is approximately the same as the footprint of the semiconductor device 110. In another embodiment of the invention, the modules 300, 400, 500, 600, and 700 occupy less area on the main printed circuit board than the devices 110, 108 and/or connectors 520, 620, 720 laterally connected on the main circuit board would occupy.

In an embodiment of the invention, the interconnecting traces between the modules 100, 200, 300, 400, 500, 600, and 700 and the main circuit board are properly terminated through impedance matching. Proper termination of the lines, in addition to shorter traces between the semiconductor devices, reduces crosstalk between the traces and reduces electromagnetic radiation (EMI) of the traces.

Another embodiment of the invention allows the modules 100, 200, 300, 400, 500, 600, and 700 to correct errors that were not corrected on the main board. For example, the module 100, 200, 300, 400, 500, 600, and 700 can be designed to correct missing or incorrect traces on the main board. Thus, reducing the complexity and cost of the main printed circuit board.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A memory module comprising:
a center section and at least one flexible wing connected to an edge of the center section;
a processor mounted onto the center section;
a plurality of memory subassemblies mounted to the at least one flexible wing, wherein the memory subassemblies form a stacked arrangement when the flexible wing folds; and
a heatsink wherein the heatsink supports the stacked arrangement of memory subassemblies, and wherein the heatsink transfers at least a portion of the heat generated by the processor and memory subassemblies away from the processor and memory subassemblies.

2. The memory module of claim 1 wherein the flexible wing comprises a rigid section and a flexible interconnect.

3. The memory module of claim 2 wherein the flexible interconnect is a polyimide flex board.

4. The memory module of claim 1 wherein the memory subassembly is random access memory, static random access memory, non-volatile random access memory, dynamic random access memory, multi-bank dynamic random access memory, synchronous dynamic random access memory, magnetoresistive random access memory, read only memory, programmable read only memory, erasable programmable read only memory, electrically erasable programmable read only memory, or flash memory.

5. The memory module of claim 1 further comprising a plurality of sockets mounted to the at least one flexible wing, wherein the memory subassemblies connect to the sockets.

6. The memory module of claim 1 wherein the heatsink comprises a base, a top section, a plurality of sides, a hollow rectangular center support, and a plurality of fins, wherein the fins support the stacked arrangement of memory subassemblies.

7. A processor/memory module comprising:
a subassembly comprising a center section and at least one flexible wing, wherein the at least one flexible wing electrically connects to an edge of the center section, and wherein the at least one wing folds over the center section;
a processor mounted to the center section;
a plurality of memory subassemblies comprising memory devices mounted to the at least one flexible wing; and
a heatsink wherein the heatsink mounts over the processor and under the at least one flexible wing, and wherein the heatsink extends beyond the processor and flexible wing to transfer heat generated by the processor and memory subassemblies away from the processor and memory subassemblies.

8. The processor/memory module of claim 7 wherein the memory subassemblies comprise single in-line memory modules.

9. The processor/memory module of claim 7 further comprising a connecting device to connect the processor/memory module to a main printed circuit board.

10. The processor/memory module of claim 9 wherein the connecting device is a ball grid array.

11. The processor/memory module of claim 7 wherein the module occupies substantially less area on a main printed circuit board than laterally interconnecting the processor and the memory devices on the main printed circuit board.

12. A test module comprising:
a center section wherein the center section electrically connects to a main printed circuit board; and
at least one foldable wing comprising at least one connector wherein the at least one foldable wing and the at least one connector electrically connect to the center section, wherein the at least one the foldable wing folds over the center section when the main printed circuit board is in a normal operation, and wherein the at least one foldable wing unfolds from over the center section and the at least one connector connects to test equipment through test equipment cables when in a test operation.

13. The test module of claim 12 further comprising a clamp to hold the wing over the center section when the main printed circuit board is in normal operation.

14. The test module of claim 12 further comprising a processor.

15. The test module of claim 12 wherein the test module tests signals from the main printed circuit board.

16. A subassembly comprising:
a center section and at least one flexible wing electrically connected to an edge of the center section;
a semiconductor device mounted onto the center section;
a plurality of connectors mounted onto the at least one flexible wing;
a plurality of integrated circuit modules wherein the modules connect to the connectors, wherein the integrated circuit modules form a stacked arrangement when the flexible wing folds; and
a heatsink wherein the heatsink supports the stacked arrangement of integrated circuit modules, and wherein the heatsink transfers at least a portion of the heat generated by the semiconductor device and integrated circuit modules away from the semiconductor and integrated circuit modules.

17. The subassembly of claim 16 wherein the integrated circuit modules comprise at least one memory device.

18. The subassembly of claim 16 wherein the flexible wing comprises polyimide flex board.

19. The subassembly of claim 16 wherein the flexible wing comprises a rigid printed circuit board and a flexible interconnect.

20. The subassembly of claim 16 wherein the heatsink comprises fins which support the stacked arrangement of modules.

21. A method of increasing the density of integrated circuits on a main assembly comprising:
providing a subassembly comprising a center section and at least one flexible wing electrically connected to an edge of the center section;
populating the center section with a semiconductor device;
populating the flexible wing with a plurality of semiconductor modules;
folding the at least one flexible wing so as to be approximately perpendicular to the center section, wherein the semiconductor modules form a stack within the subassembly;
supporting the stack of semiconductor modules with a heatsink; and
connecting the subassembly to a main assembly.

22. The method of claim 21 further comprising populating the flexible wing with a plurality of sockets, wherein the semiconductor modules connect to the sockets.

23. The method of claim 21 wherein the semiconductor modules comprise memory boards.

24. The method of claim 21 semiconductor device comprises a processor.

25. A subassembly comprising:
a center section and at least one flexible wing electrically connected to an edge of the center section,
a semiconductor device mounted onto the center section;
a plurality of integrated circuit modules mounted to the at least one flexible wing, wherein the integrated circuit modules form a stacked arrangement when the flexible wing folds so as to be approximately perpendicular to the semiconductor device; and
a means to support the stacked arrangement of modules and to transfer at least a portion of the heat generated by the semiconductor device and integrated circuit modules away from the semiconductor device and integrated circuit modules.

26. The subassembly of claim 25 further comprising a means to mount the plurality of integrated circuit modules to the at least one flexible wing.

27. The subassembly of claim 26 wherein the means to mount comprises at least one socket.

28. The subassembly of claim 25 wherein the means to support and to transfer heat comprises a heatsink.

29. A memory module comprising:
a center section and at least one flexible wing connected to an edge of the center section;
at least one socket mounted to the flexible wing; and
at least one memory board connected to the socket on the at least one flexible wing.

30. The memory module of claim 29 further comprising a heatsink, wherein the heatsink supports an edge of the memory board.

31. The memory module of claim 29 further comprising a semiconductor device mounted to the center section.

32. The memory module of claim 31 wherein the semiconductor device comprises a processor.

33. The memory module of claim 29 wherein the memory boards form a stacked arrangement when the flexible wing folds.

34. The memory module of claim 29 wherein the memory boards are random access memory, static random access memory, non-volatile random access memory, dynamic random access memory, multi-bank dynamic random access memory, synchronous dynamic random access memory, magnetoresistive random access memory, read only memory, programmable read only memory, erasable programmable read only memory, electrically erasable programmable read only memory, or flash memory.

35. The memory module of claim 29 wherein the socket comprises an in-line connector.

36. A method of increasing the density of integrated circuits on a main assembly comprising:
providing a center section and at least one flexible wing electrically connected to an edge of the center section;
mounting at least one socket on the flexible wing;
connecting a memory board to the at least one socket;
folding the at least one flexible wing, wherein the memory board forms a stack within the subassembly; and
connecting the subassembly to a main assembly.

37. The method of claim 36 further comprising supporting the stack with a heatsink.

38. The method of claim 36 further comprising mounting a semiconductor device to the center section.

39. The method of claim 36 further comprising mounting at least one socket to the center section.
